(19) United States
(12) Patent Application Publication
(10) Pub. No.: US 2008/0311730 A1
(43) Pub. Date: Dec. 18, 2008

(54) SEMICONDUCTOR DEVICE AND METHOD OF FORMING GATE THEREOF

(76) Inventor: Yong-Ho Oh, Gangnam-gu (KR)

Correspondence Address: SHERR & VAUGHN, PLLC, 620 HERNDON PARKWAY, SUITE 200, HERNDON, VA, 20170, US

(21) Appl. No.: 12/136,793

(22) Filed: Jun. 11, 2008

(30) Foreign Application Priority Data
Jun. 15, 2007 (KR) 10-2007-0059028

(51) Int. Cl. H01L 21/20

(52) U.S. Cl. 438/479; 257/E21.09

(57) ABSTRACT

A method of forming a gate of a semiconductor device includes providing a semiconductor substrate in which an active region is defined by isolation films, forming a gate insulating film on the active region, forming a capping film on the gate insulating film, and performing an annealing process on the resulting surface and then forming a gate in part of the active region. The capping film is formed on the gate insulating film to prevent a reaction between the gate insulating film and subsequent gate materials, thereby preventing a phenomenon in which the work function of a gate changes and also the creation of a gate insulator having a low dielectric constant. The annealing process is performed under fluorine gas ambient to prevent trap sites within the gate insulating film while the gate can be composed of a metal or fully silicided gate to reduce the EOT.

The present application claims priority under 35 U.S.C. 119 to Korean Patent Application No. 10-2007-0059028 (filed on Jun. 15, 2007), which is hereby incorporated by reference in its entirety.

### BACKGROUND

As semiconductor devices become highly integrated and the feature size of an MOS field effect transistor (MOSFET) decreases, the gate length and the length of a channel formed under the gate also decrease. Accordingly, in order to increase capacitance between the gate and the channel and also improve the operating characteristics of the transistor, it is necessary to form a gate insulating film having a thin thickness. However, a gate insulating film made of a silicon oxide film or a silicon oxynitride film, which has so far been used representatively, has encountered physical limitations in terms of its electrical properties due to the reduced thickness and is difficult to ensure reliability of the gate insulating film. Accordingly, when a gate insulating film is formed of a silicon oxide film or a silicon oxynitride film, there is a limitation to its reduction in the thickness.

In order to overcome the above problems, active research has been done on a high-k film made of alternative materials to silicon oxide film and silicon oxynitride film which can reduce leakage current between a gate electrode and a channel region while maintaining a thin equivalent oxide thickness (EOT). However, in the case in which a high-k film is used as the gate insulating film of a MOSFET semiconductor device, problems arise because electron mobility at the channel region formed in a semiconductor substrate under the gate insulating film decreases due to a number of bulk traps and also an interface trap at the interface between the semiconductor substrate and the gate insulating film. Moreover, the threshold voltage (Vt) abnormally rises when compared with a gate insulating film made of silicon oxide film or silicon oxynitride film. In order to overcome the above problems and reduce a poly depletion effect, i.e., a problem in devices using a gate made of polysilicon, a MOSFET device structure employing a fully silicided (FUSI) gate and a metal gate was developed.

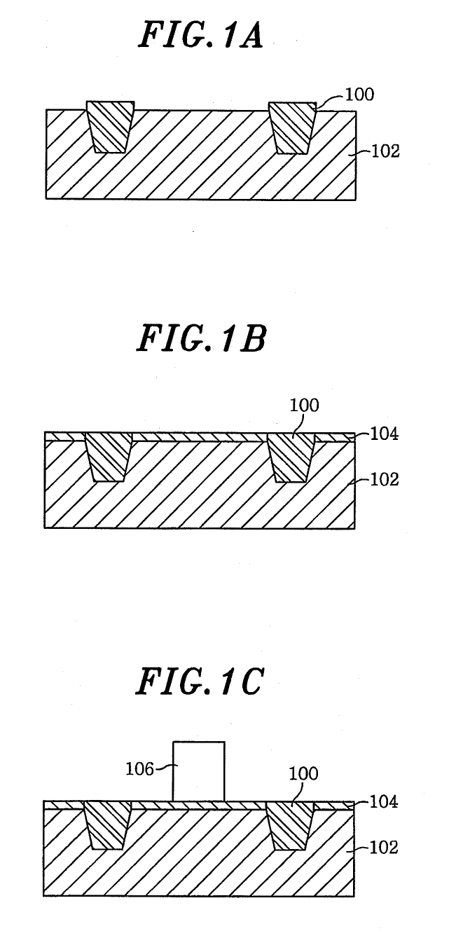

As illustrated in example FIG. 1A, a process of forming a gate of a semiconductor device can include semiconductor substrate 102 in which isolation films 100 for defining an active region are formed. Semiconductor substrate 102 can be a silicon substrate or a silicon-on-insulator (SOI) substrate and doped with a P-type or N-type impurity.

As illustrated in example FIG. 1B, a material having a high dielectric constant, for example, HfO₂ is deposited on and/or over semiconductor substrate 102, thus forming gate insulating film 104. Gate insulating film 104 is formed only on and/or over the active region. If, as described above, gate insulating film 104 formed of a material having a high dielectric constant, such as HfO₂, is deposited on and/or over semiconductor substrate 102, an insulating film having a low dielectric constant is generated through the reaction of silicon (Si) of semiconductor substrate 102 with HfO₂. Accordingly, there are problems in that the EOT of gate insulating film 104 increases, the mobility speed of carriers decreases, etc., thereby degrading device characteristics. To solve these problems, an annealing process may be performed before the gate is formed, an insulating film with a low dielectric constant can be prevented from being formed due to the reaction of silicon (Si) of semiconductor substrate 102 with HfO₂.

As illustrated in example FIG. 1C, metal or fully silicided gate 106 is formed on and/or over the entire resulant surface using a conductive material, for example, a metal or a silicide. However, if gate insulating film 104 is formed of a HfO₂-based material with a high-k in the MOSFET using the metal or fully silicided gate 106, Vₜ increases due to a fermi-level pinning phenomenon caused by Hf—Si bonding at the surface of the HfO₂ material having a high dielectric constant and polysilicon, thus degrading device characteristics. In other words, the performance of the semiconductor device is degraded since the work function of metal or fully silicided gate 106 changes due to trap sites within a high-k material such as HfO₂.

### SUMMARY

Embodiments relate to a semiconductor and a method forming thereof including a gate insulating film made of a high dielectric constant (high-k) material.

Embodiments relate to a method of forming a gate of a semiconductor device which can prevent the creation of insulating materials having a low dielectric constant after a gate insulating film is formed of a high dielectric constant and also prevent the cause occurrence of a fermi-level pinning phenomenon.

Embodiments relate to a method of forming a gate of a semiconductor device that can include at least one of the following steps: providing a semiconductor substrate having an active region defined by isolation films; and then forming a gate insulating film on and/or over the active region; and then forming a capping film on and/or over the gate insulating film; and then performing an annealing process on the resulting surface; and then forming a gate in a portion of the active region. In accordance with embodiments, the gate insulating film may be formed of a metal oxide material having a high dielectric constant using an atomic layer deposition (ALD) method. The capping film can be formed of amorphous silicon using at least one of a chemical vapor deposition (CVD) method, a physical vapor deposition (PVD) method and a sputtering process. The capping film can have a thickness of between 2 to 5 nm. The annealing process can be performed using fluorine (F) gas, or a mixture gas including fluorine (F) gas. At the time of the annealing process, a temperature ranging from between 350 to 750 degrees Celsius can be used. The gate can include a silicide gate or a metal gate using at least one of TaN, TiN, HfN and La.

Embodiments relate to a method of forming a gate on a semiconductor device that can include at least one of the following steps: providing a semiconductor substrate having an active region defined by isolation films formed therein; and then forming a gate insulating film on the active region; and then forming a capping film on the gate insulating film; and then performing an annealing process on the capping film; and then forming the gate on the capping film in the active region.

Embodiments relate to a semiconductor device that can include at least one of the following: a semiconductor substrate having an active region defined by isolation films; an annealed gate insulating film formed on the active region; an annealed capping film formed on the annealed gate insulating film; and a gate formed on the annealed capping film in the active region.

Embodiments relate to a method of forming a semiconductor device that can include at least one of the following steps: sequentially forming a gate insulating film and an amorphous silicon film on a semiconductor substrate, wherein the gate insulating film is formed in an active region of the semiconductor substrate and composed of a high dielectric constant material; and then performing an annealing process on the semiconductor substrate including the amorphous silicon film and the gate insulating film; and then forming a gate on the amorphous silicon film in the active region.

### DRAWINGS

Example FIGS. 1A to 1C illustrate a process of forming a gate of a semiconductor device.

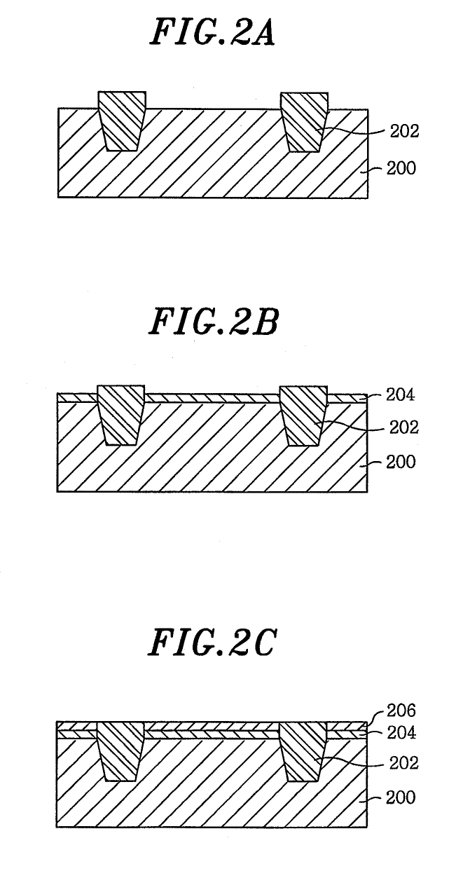

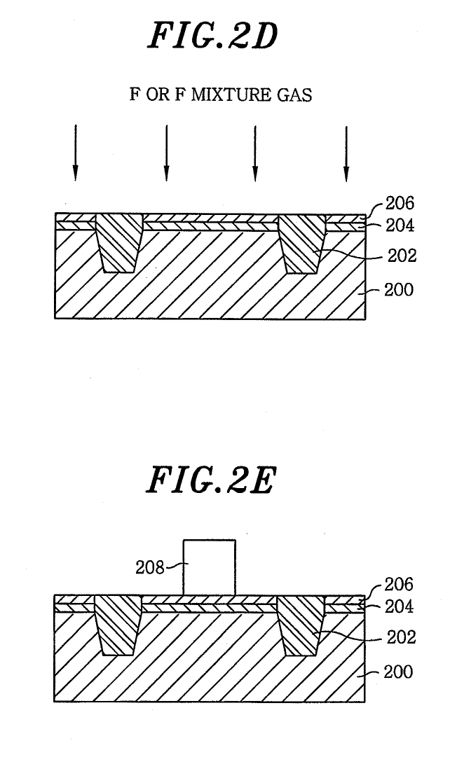

Example FIGS. 2A to 2E illustrate a process of forming a gate of a semiconductor device, in accordance with embodiments.

### DESCRIPTION

As illustrated in example FIG. 2A, there is provided semiconductor substrate 200 in which an active region is defined by isolation films 202. Semiconductor substrate 200 may be at least one of a silicon substrate or SOI substrate, and may be doped with a P-type or an N-type impurity or have P-type and N-type wells formed therein.

As illustrated in example FIG. 2B, gate insulating film 204 may be formed on and/or over the active region of semiconductor substrate 200 using a material having a high dielectric constant such as metal oxide. Gate insulating film 204 including the metal oxide material can be formed using an ALD method. Examples of metal oxide materials having a high dielectric constant may include tantalum oxide (Ta₂O₅), titanium oxide (TiO₂), hafnium oxide (HfO₂), zirconium oxide (ZrO₃), alumina (Al₂O₃), AlₓO_{y}N_{z} (nitride aluminum), hafnium aluminum (HfAlₓO_{y}), Y₂O₃ (iridium oxide), Nb₂O₅ (niobuim oxide), cesium oxide (CeO₂), indium oxide (InO₃), lanthanum oxide (LaO₂), etc. However, any one or a combination of two or more of the above compounds may be used as the metal oxide material.

As illustrated in example FIG. 2C, thin capping film 206 may then be formed on and/or over gate oxide film 204. Capping film 206 can be formed of amorphous silicon having a thickness of between 2 to 5 nm, and can be formed using at least one of a chemical vapor deposition (CVD) method, a physical vapor deposition (PVD) method, a sputtering process or the like. As described above, if capping film 206 made of amorphous silicon is formed after formation of gate insulating film 204 composed of a high dielectric constant material, a chemical reaction between gate insulating film 204 and a subsequent gate material is prohibited, so that a phenomenon in which the work function of the gate changes can be prohibited.

As illustrated in example FIG. 2D, an annealing process may then be performed on the resulting surface of FIG. 2C, as shown in FIG. 2D. Here, the annealing process can be performed under ambient condition, including fluorine (F) gas or a mixture gas including fluorine (F) gas, and can be performed in a temperature range of 350 to 750 degrees Celsius. If the annealing process is carried out as described above, trap sites occurring within the material having a high dielectric constant, i.e., gate insulating film 204, can be prevented.

As illustrated in example FIG. 2E, metal or fully silicided gate 208 may then be formed on and/or over the active region. Gate 208 can be formed of a metal such as at least one of TaN, TiN, HfN and La. By forming metal or fully silicided gate 208 as described above, the EOT can be reduced.

In accordance with embodiments, after forming gate insulating film 204 of a material having a high dielectric constant, capping film 206 made of amorphous silicon can then be formed on and/or over gate insulating film 204. An annealing process may then be carried out on capping film 206. Accordingly, a phenomenon in which insulating materials having a low dielectric constant are created can be prevented, and the cause of a fermi-level pinning phenomenon can also be prevented.

As described above, in accordance with embodiments, after formation of a gate insulating film composed of material with a high dielectric constant, a capping film is formed of amorphous silicon to prevent a reaction between the gate insulating film and subsequent gate materials. Accordingly, not only a phenomenon in which the work function of a gate changes can be prohibited, but also the creation of an insulator having a low dielectric constant can be prevented. Consequent, the performance of semiconductor devices can be improved.

Moreover, in accordance with embodiments, after sequentially forming a gate insulating film with composed of a high dielectric constant material and a capping film, an annealing process is performed under fluorine gas ambient. Accordingly, there is an advantage in that trap sites within the gate insulating film can be prevented. Moreover, embodiments can reduce the EOT effectively by forming a metal or fully silicided gate.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a gate of a semiconductor device comprising:
providing a semiconductor substrate having an active region defined by isolation films formed therein; and then
forming a gate insulating film on the active region; and then
forming a capping film on the gate insulating film; and then
performing an annealing process on the semiconductor having the capping film and the gate insulating film; and then
forming the gate on the capping film in the active region.

2. The method of claim 1, wherein the gate insulating film is composed of a metal oxide material having a high dielectric constant.

3. The method of claim 2, wherein the gate insulating film is formed using an atomic layer deposition (ALD) method.

4. The method of claim 1, wherein the capping film is composed of amorphous silicon.

5. The method of claim 4, wherein the capping film is formed using at least one of a chemical vapor deposition method, a physical vapor deposition method and a sputtering process.

6. The method of claim 1, wherein the capping film has a thickness of between 2 to 5 nm.

7. The method of claim 1, wherein the annealing process is performed using at least one of fluorine gas and a mixture gas including fluorine gas.

8. The method of claim 7, wherein the annealing process is performed in a temperature range of between 350 to 750 degrees Celsius.

9. The method of claim 1, wherein the gate comprises a fully silicided gate.

10. The method of claim 1, wherein the gate comprises a metal gate selected from a group consisting of TaN, TiN, HfN and La.

11. A semiconductor device comprising:
a semiconductor substrate having an active region defined by isolation films;
an annealed gate insulating film formed on the active region;
an annealed capping film formed on the annealed gate insulating film; and
a gate formed on the annealed capping film in the active region.

12. The semiconductor of claim 11, wherein the gate insulating film is composed of a metal oxide material having a high dielectric constant.

13. The semiconductor device of claim 11, wherein the capping film is composed of amorphous silicon.

14. The semiconductor device of claim 1, wherein the capping film has a thickness of between 2 to 5 nm.

15. The semiconductor device of claim 11, wherein the gate comprises a fully silicided gate.

16. The semiconductor device of claim 11, wherein the gate comprises a metal gate selected from a group consisting of TaN, TiN, HfN and La.

17. A method of forming a semiconductor device comprising:
sequentially forming a gate insulating film and an amorphous silicon film on a semiconductor substrate, wherein the gate insulating film is formed in an active region of the semiconductor substrate and composed of a high dielectric constant material; and then
performing an annealing process on the semiconductor substrate including the amorphous silicon film and the gate insulating film; and then
forming a gate on the amorphous silicon film in the active region.

18. The method of claim 17, wherein the gate comprises a fully silicided gate.

19. The method of claim 17, wherein the gate comprises a metal gate selected from a group consisting of TaN, TiN, HfN and La.

20. The semiconductor of claim 17, wherein the high dielectric constant material comprises a metal oxide.
